(19) United States
(12) Patent Application Publication
(10) Pub. No.: US 2008/0179656 A1
(43) Pub. Date: Jul. 31, 2008

(54) SEMICONDUCTOR DEVICE, NONVOLATILE SEMICONDUCTOR MEMORY DEVICE AND MANUFACTURING METHOD OF SEMICONDUCTOR DEVICE

(75) Inventor: Nobutoshi AOKI, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/020,827

(22) Filed: Jan. 28, 2008

(30) Foreign Application Priority Data
Jan. 26, 2007 (JP) 2007-016532

(51) Int. Cl. H01L 29/00; H01L 21/3205

(52) U.S. Cl. 257/316; 438/593; 257/E21.294; 257/E29.001

(57) ABSTRACT

In one aspect of the present invention, A semiconductor device, may include a transistor including a semiconductor substrate, an insulating film formed on the semiconductor substrate, and a gate stacked above the semiconductor substrate with the insulating film placed in between, and element isolation trenches formed in the semiconductor substrate to define an element formation region in which the transistor is to be formed, wherein the semiconductor substrate includes a narrow portion therein, the narrow portion formed by partially narrowing down the element formation region from the side surfaces of the element isolation trenches in the gate width directions in the substrate.

### CROSS REFERENCE TO RELATED APPLICATION

This application is based upon and claims the benefit of priority from Japanese Patent Application No. 2007-16532, filed on Jan. 26, 2007, the entire contents of which are incorporated herein by reference.

### BACKGROUND

In a semiconductor device where large number of miniaturized transistors are arrayed, a short channel effect and a narrow channel effect are quite likely to occur. As a method for reducing the short channel effect and the narrow channel effect, an SOI (Silicon on Insulator) substrate has so far been used. However, the SOI substrate has problems of not only high costs for manufacturing, but also difficulty in electrically control due to a substrate floating effect.

Hereinafter, descriptions will be given of an electrically erasable and programmable read only memory (EEPROM) as an example.

A NAND-type flash memory has so far been known as one of the EEPROMs. In the NAND-type flash memory, multiple electrically rewritable nonvolatile memory cells are serially connected to form a NAND cell unit. Accordingly, the NAND-type flash memory has a unit cell area smaller than a NOR-type, and therefore is easily increased in capacity.

The NAND-type flash memory utilizes an FN tunnel current in writing data therein, while a NOR-type flash memory utilizes hot carrier injection. Accordingly, the NAND-type flash memory consumes a smaller amount of current than the NOR-type flash memory. As a result, a page capacity for simultaneous writing data can be increased. This enables high speed data writing in practice.

It is necessary to scale down an element isolation region to achieve further miniaturization of the NAND-type flash memory cell. However, the scaling down of the element isolation region results in the reduction in the voltage resistance between cells. To achieve the miniaturization of the cell without bringing about the reduction in voltage resistance, a technique of forming a memory cell array including NAND cell units on an SOI substrate is effective. The use of the SOI substrate allows a p-n junction capacitance to be reduced as compared to the case where wells are formed in a single substrate, and therefore provides an advantage that the NAND-type flash memory can be operated at high speed.

Thus, the NAND-type flash memory using the SOI substrate has already been proposed. However, in the NAND-type flash memory manufacture by use of the SOI substrate, the channel bodies of the memory cells are separated from the silicon substrate by the insulating layer. This separation makes it difficult to collectively apply an erasing voltage to the channel bodies of all memory cells from the substrate side.

### SUMMARY

Aspects of the invention relate to an improved semiconductor device, a nonvolatile semiconductor memory device and a manufacturing method of semiconductor device.

In one aspect of the present invention, A semiconductor device, may include a transistor including a semiconductor substrate, an insulating film formed on the semiconductor substrate, and a gate stacked above the semiconductor substrate with the insulating film placed in between, and element isolation trenches formed in the semiconductor substrate to define an element formation region in which the transistor is to be formed, wherein the semiconductor substrate includes a narrow portion therein, the narrow portion formed by partially narrowing down the element formation region from the side surfaces of the element isolation trenches in the gate width directions in the substrate.

In another aspect of the invention, a nonvolatile semiconductor memory device may include a plurality of memory cells each including a semiconductor substrate, a first insulating film formed on the semiconductor substrate, a floating gate formed above the semiconductor substrate with the first insulating film placed in between, a second insulating film formed on the floating gates, and a control gate formed above the floating gate with the second insulating film placed in between, and element isolation trenches extending in the gate length directions to isolate from each other the memory cells adjacent in the gate width directions, wherein the semiconductor substrate includes a narrow portion therein, the narrow portion formed by partially narrowing down an element formation region of the substrate from the side surfaces of the element isolation trenches in the gate width directions, the element formation region defined by the element isolation trenches.

In another aspect of the invention, a method for manufacturing a semiconductor device, may include forming an insulating film on a semiconductor substrate, forming an electrode layer to serve as a gate electrode on the insulating film, forming element isolation trenches extending from the electrode layer to the inside of the semiconductor substrate to define an element formation region in the semiconductor substrate, selectively etching the side surfaces of the element isolation trenches of the semiconductor substrate to engrave a portion of the semiconductor substrate in directions approximately perpendicular to the side surfaces, the portion of the semiconductor substrate being in the element formation region below the top surface of the substrate, and filling the element isolation trench with an element isolation insulating film after selectively etching the side surfaces.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a plan view of a cell region of a NAND-type EEPROM (nonvolatile semiconductor memory device) according to the first embodiment of the present invention.

FIG. 2 is a cross-sectional view taken along one of the bit lines BL of the NAND-type EEPROM according to the first embodiment (I-I′ sectional view of FIG. 1).

FIG. 3 is a cross-sectional view taken along one of the word lines WL (II-II′ sectional view in FIG. 1).

FIGS. 4-9 are cross-sectional views showing a manufacturing process of the nonvolatile semiconductor memory device according to the first embodiment.

FIG. 10 is an equivalent circuit diagram of the nonvolatile semiconductor memory device and a diagram showing a voltage applied to the wiring in erase, write and read mode, respectively.

FIG. 11 is a cross-sectional view taken along II-II, sectional view in FIG. 1 of the NAND-type EEPROM according to the second embodiment.

FIG. 12 is a cross-sectional view taken along I-I′ sectional view of FIG. 1 of the NAND-type EEPROM according to the second embodiment.

FIGS. 13-22 are cross-sectional views showing a manufacturing process of the nonvolatile semiconductor memory device according to the second embodiment.

FIG. 23 diagrammatically shows the main part of the embodiment.

FIG. 24 diagrammatically shows the impurity concentration distribution of the second embodiment.

FIGS. 25 and 26 show carrier concentration distributions in the silicon substrates and the polysilicon layers obtained by simulation in order to show the electric properties of the embodiment in comparison with those of conventional examples.

FIG. 27 shows relationships between the voltage applied to the silicon substrate and the p-n junction capacities.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### FIRST EMBODIMENT

### Structure of the First Embodiment

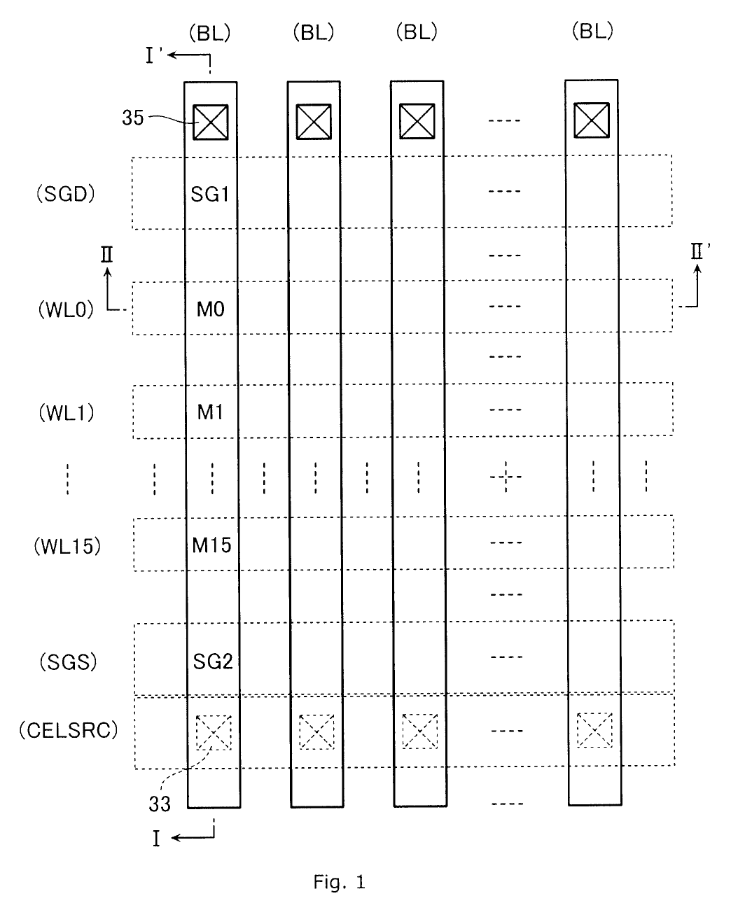

FIG. 1 is a plan view of a cell region of a NAND-type EEPROM (nonvolatile semiconductor memory device) according to the first embodiment of the present invention. Multiple bit lines BL vertically extending in the figure is formed in the cell region. In a layer below these bit lines BL, select gates SG (SGD, and SGS), a common source line CELSRC and multiple word lines WL are formed. The select gates SG (SGD, and SGS) and the common source line CELSRC extend horizontally to be perpendicular to the bit lines BL. The word lines WL (WL 0 to 15) sandwiched between the select gates SGD and SGS and extending in parallel to the select gates SG and the common source line CELSRC.

Memory cells M (M 0 to 15) are formed beneath the intersections between the word lines WL and each of the bit lines BL. Select gate transistors SG are formed beneath the intersections between the select gates SG and each of the bit lines BL.

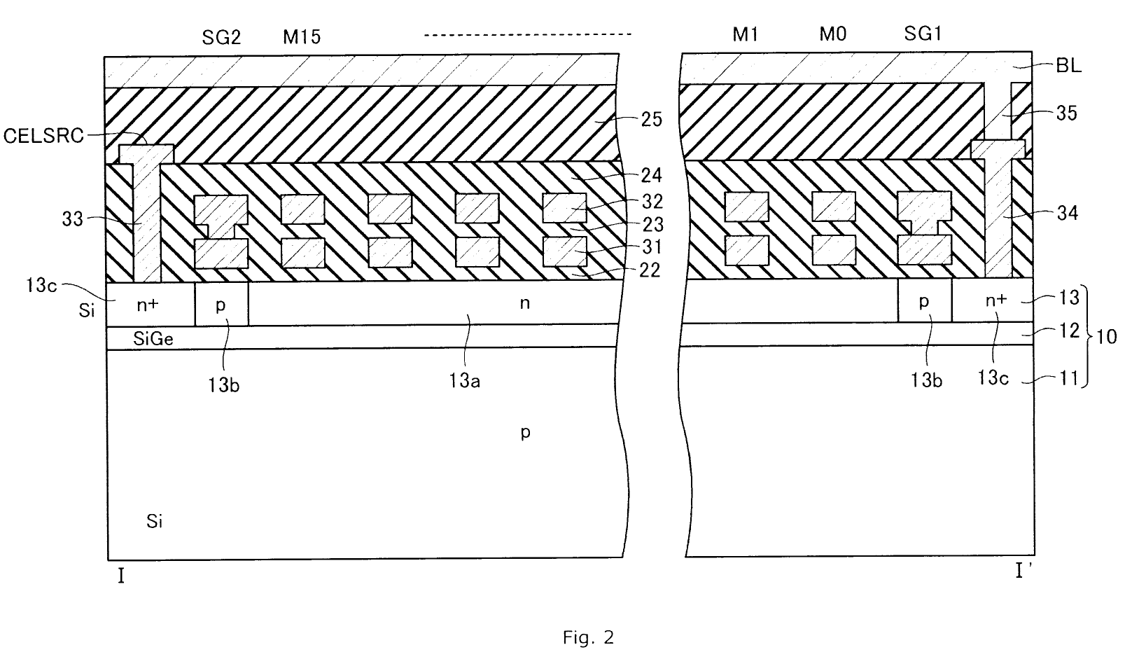

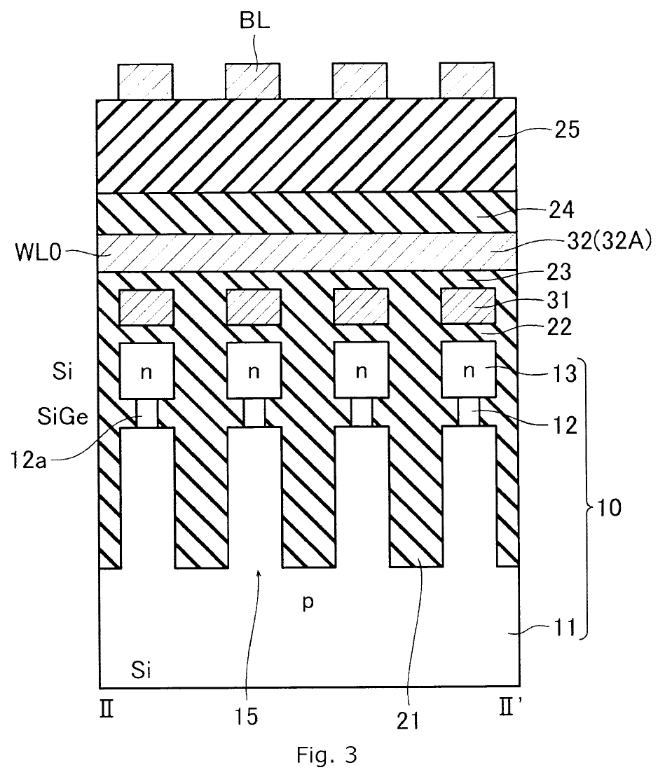

FIG. 2 is a cross-sectional view taken along one of the bit lines BL of the NAND-type EEPROM according to the present embodiment (I-I′ sectional view of FIG. 1). FIG. 3 is a cross-sectional view taken along one of the word lines WL (II-II′ sectional view in FIG. 1).

As shown in FIGS. 2 and 3, a semiconductor substrate 10 includes a silicon substrate 11, a thin silicon germanium layer 12 formed on the silicon substrate 11, and a silicon layer 13 formed on the silicon germanium layer 12.

The silicon germanium layer 12 connects the silicon substrate 11 and the silicon layer 13 only in a center portion in the direction of the word lines WL, and forms narrow portions 12a in the semiconductor substrate 10. In the silicon layer 13, the sections corresponding to the memory cells M and the select gate transistors SG form active regions. The silicon substrate 11 and the silicon layer 13 are of p-type in this example. As shown in FIG. 2, in regions of the silicon layer 13 in which memory cells M are formed (channel bodies, and source and drain regions), an n-type diffusion layer 13a is formed by ion implantation. Note that regions at the both ends of the memory cell formation region, where the channel bodies of the select gates SG1 and SG2 are to be formed, remain p-type regions 13b. Furthermore, adjacent to the outer sides of the select gate transistors SG1 and SG2, n+-type contact regions 13c are formed.

As shown in FIG. 3, the semiconductor substrate 10 has stripe-like element formation regions 15 defined by an isolation insulating film 21. Specifically, the isolation insulating film 21 is formed in regions each between two adjacent bit lines BL using STI (shallow trench isolation), and thereby the element formation regions 15 are isolated from each other in the direction of the word lines WL. In each element formation region 15, a floating gate 31 serving as an electric charge accumulation layer is formed above the silicon layer 13 with a tunnel oxide film 22 placed in between. Moreover, control gates 32 are formed above the floating gates 31 with an intergate insulating film 23. As shown in FIG. 2, each select gate transistor SG is formed as a usual transistor by short-circuiting the floating gate 31 and the control gate 32.

The floating gate 31 is individually formed for each memory cell in an isolated manner. The control gate 32 is formed continuously in one direction and serves as the word lines WL each common to the multiple memory cells M, or as the select gate SGD or SGS common to the multiple select gate transistors SG. As the floating gate 31, a polycrystalline silicon film is used herein, but an insulative electric charge accumulation layer can alternatively be used.

The control gates 32 are covered with interlayer insulating films 24 and 25. On the interlayer insulating film 24, the common source line CELSRC is formed. The common source line CELSRC is in contact, via a contact plug 33, with the contact regions 13c that serve as the source regions of the select gate transistors SG2. On the interlayer insulating film 25, the bit lines BL are formed. The bit lines BL are in contact, via contact plugs 34 and 35, with the contact regions 13c that serve as the drain regions of the select gate transistors SG1.

### Manufacturing Method of the First Embodiment

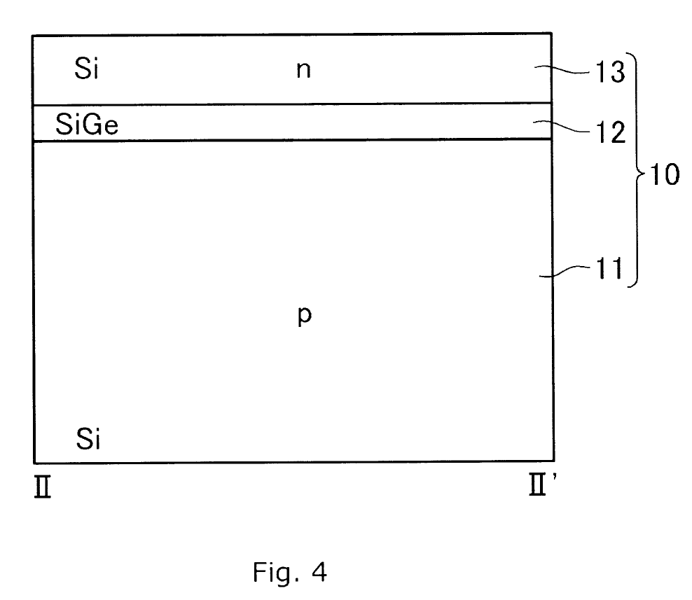

Hereinafter, a method for manufacturing the NAND-type EEPROM according to the first embodiment described above will be described with reference to FIGS. 4 to 9.

As shown in FIG. 4, a silicon germanium (SixGe(1-x)) layer 12 is formed on the silicon substrate 11 by an epitaxial growth method. The composition ratio (x) of Si and Ge in the silicon germanium layer 12 can be set at any value. However, too large composition ratio x can trigger a lattice defect. Accordingly, x should be within a range of 0.1 to 0.5, for example 0.2.

An n-type silicon layer 13 is then formed on the silicon germanium layer 12 by an epitaxial growth method. The thicknesses of the silicon germanium layer 12 and the silicon layer 13 can be set at any value. In the present embodiment, the thicknesses of the silicon germanium layer 12 and the silicon layer 13 are set to 5 nm and 10 nm, respectively.

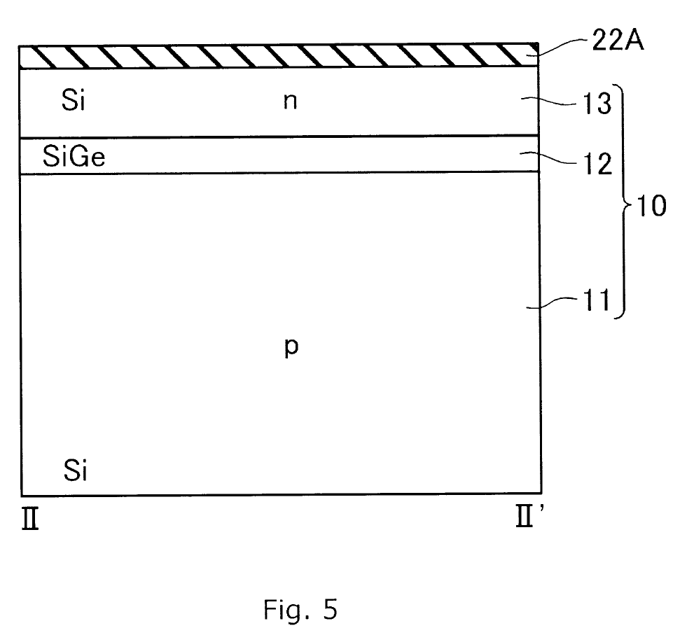

As shown in FIG. 2, an n-type diffusion layer 13a is then formed by implanting ions of a n-type impurity into the a region of the silicon layer 13 in which the memory cells M are formed (channel bodies, and source and drain regions of the memory cells). As shown in FIG. 5, an oxide film 22A serving as a tunnel oxide film 22 is subsequently formed on the silicon layer 13. The oxide film 22A may be formed by either heat-oxidizing the surface of the silicon layer 13, or stacking an oxide thereon. The thickness of the oxide film 22A can be set at any value, and is set to 5 nm in the present embodiment.

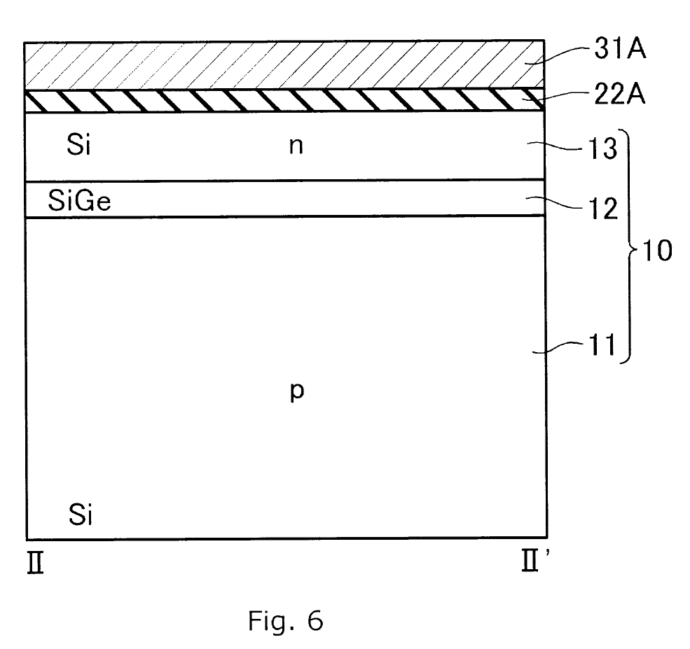

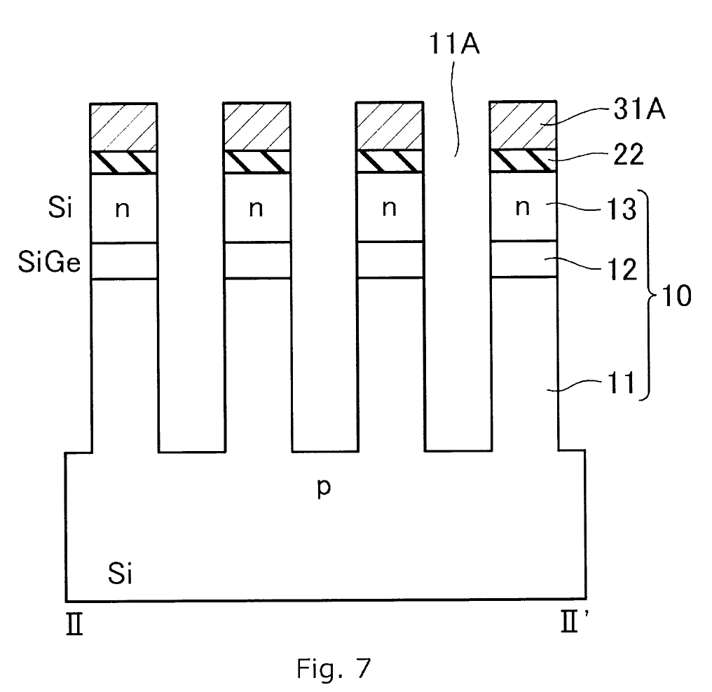

As shown in FIG. 6, a polysilicon layer 31A to serve as the floating gates 31 is then formed on the oxide film 22A. Thereafter, trenches 11A for the STI are formed as shown in FIG. 7 by first patterning a resist film by using a standard lithography technique, and by then etching the polysilicon layer 31A, the oxide film 22A, the silicon layer 13, the silicon germanium layer 12, and silicon substrate 11 to a desired depth by anisotropic etching using an reactive ion etching (RIE) method or the like. FIG. 7 shows the state in which the resist film is removed after etching.

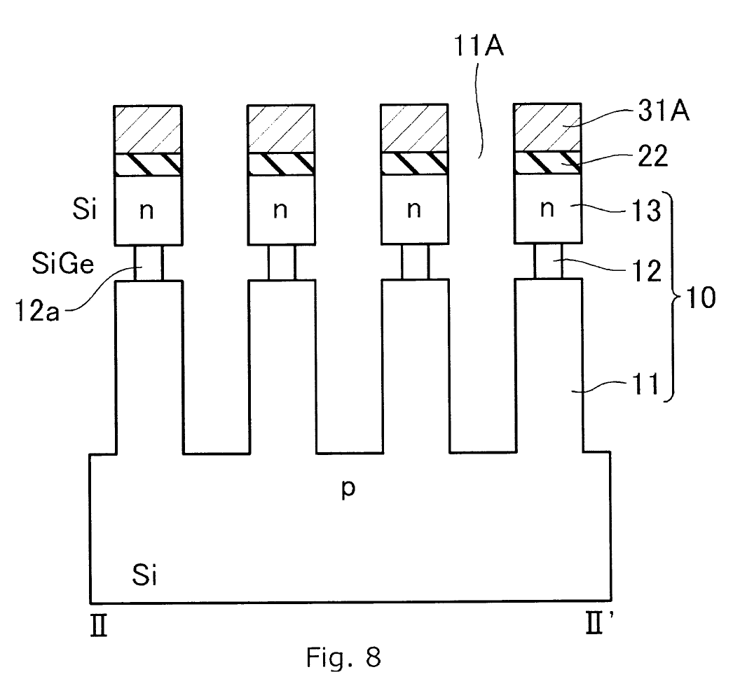

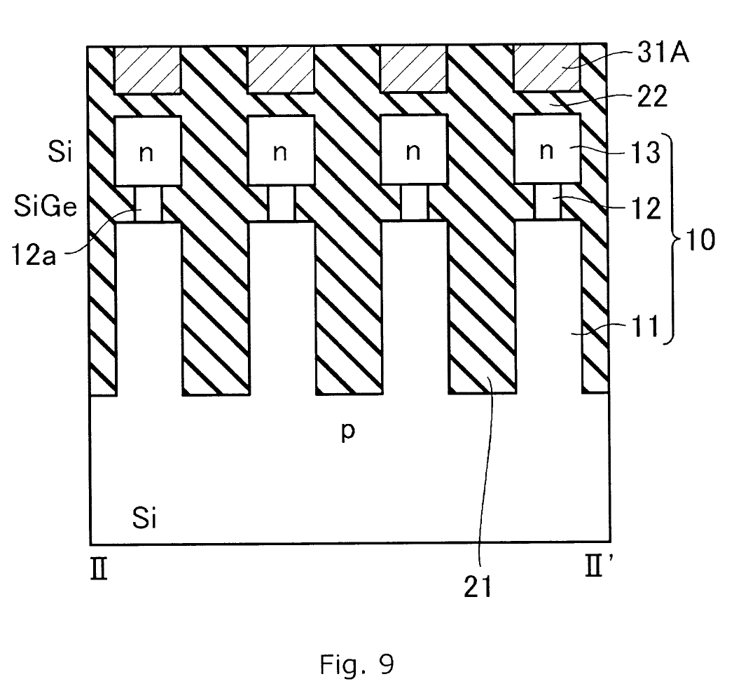

As shown in FIG. 8, narrow portions 12a are then formed by removing the silicon germanium layer 12 in horizontal directions (gate width directions) at a predetermined width from the side surfaces of the formed trenches 11A. To be specific, by using, for example, an acid solution such as a hydrogen peroxide solution as an etching solution, only silicon germanium layer 12 is selectively etched, and thereby partially engraved in horizontal directions. Thereafter, the trenches 11A for the STI and concave portions of the silicon germanium layer 12 engraved in horizontal directions are filled with an oxide film, and thereby an element isolation insulating film 21 shown in FIG. 9 is formed.

Through the element isolating process, the silicon layer 13, the silicon germanium layer 12 and an upper portion of the silicon substrate 11 are patterned as multiple stripe-like element formation regions 15. Each stripe-like element formation region is continuous in the direction of the bit lines BL, each of which includes a narrow portion 12a, and separated from each other in the direction of the word lines WL. At the same time, the polysilicon layer 31A to serve as floating gates is patterned in stripe-like shapes similarly as the element formation regions 15.

Subsequently, a polysilicon layer 32A for forming a control gate 32 is formed after an intergate insulating film 23 is formed as shown in FIG. 3. Thereafter, the polysilicon layer 32A is patterned to form the word lines WL and the select gate lines SGD and SGS. In the process of patterning the polysilicon layer 32A, the polysilicon layer 31A to form the floating gates 31 are also etched in order to form the floating gates 31 isolated from each other in the direction of the channel lengths of the cells. In each of the select gate transistors SG, the polysilicon layers 31A and 32A are short-circuited by first forming a contact hole in the intergate insulating film 23 in the select gate transistor SG, and by then filling the contact hole with a portion of the polysilicon layer 32A as shown in FIG. 2.

Contact regions 13c comprised of n+-type diffusion layer are then formed by implanting ions into the positions in contact with the bit lines and the common source line CELSRC shown in FIG. 2. Thereafter, an interlayer insulating film 24 is formed on the control gate 32. Contact holes are formed in the interlayer insulating film 24 at positions corresponding to the contact regions 13c, thereby the contact plugs 33 and 34 which are in contact with the contact region 13c are formed. At the same time, the common source line CELSRC is also formed. Furthermore, an interlayer insulating film 25 is formed on both the interlayer insulating film 24 and the common source line CELSRC. Subsequently, a contact hole is formed in the interlayer insulating film 25 at a position corresponding to each contact plug 34. Then, the contact hole is filled to form a contact plug 35. Thereafter, bit lines BL are formed on the top surface of the interlayer insulating film 25. The EEPROM of the present embodiment shown in FIGS. 1 to 3 is thereby provided.

### Operation of the Semiconductor Device of the First Embodiment

The operation of the NAND-type EEPROM of the present embodiment which is constructed in the above manner will then be described.

In the NAND-type EEPROM of the present embodiment, each of the multiple memory cells M uses the n-type diffusion layer 13a, as a channel body, and source and drain regions, without having source and drain regions particularly formed in the n-type diffusion layer 13a. Thus, the multiple memory cells M are connected in series while sharing the source and drain regions with adjacent memory cells M. Accordingly, the memory cells M can serve as depletion (D) type n-channel transistors in a built-in state. On the other hand, the select gate transistors SG1 and SG2 are formed above the p-type regions 13b to serve as enhancement (E) type n-channel transistors which are cut off at a gate voltage of 0 V.

Therefore, data is written in each memory cell M by injecting electrons into the corresponding floating gate 31 to make the memory cell M in an E-type state where a threshold value is positive. The state in which the threshold value is positive is called, for example, data “0.”

On the other hand, data is erased from each memory cell M by releasing the electrons in the corresponding floating gate 31 to cause the memory cell M to have a negative threshold value (in a D-type state). The state in which the data is erased is called, for example, data “1.” Data can be erased in a unit of erase, that is, a block defined as a group of memory cells in a NAND cell unit sharing a word line WL.

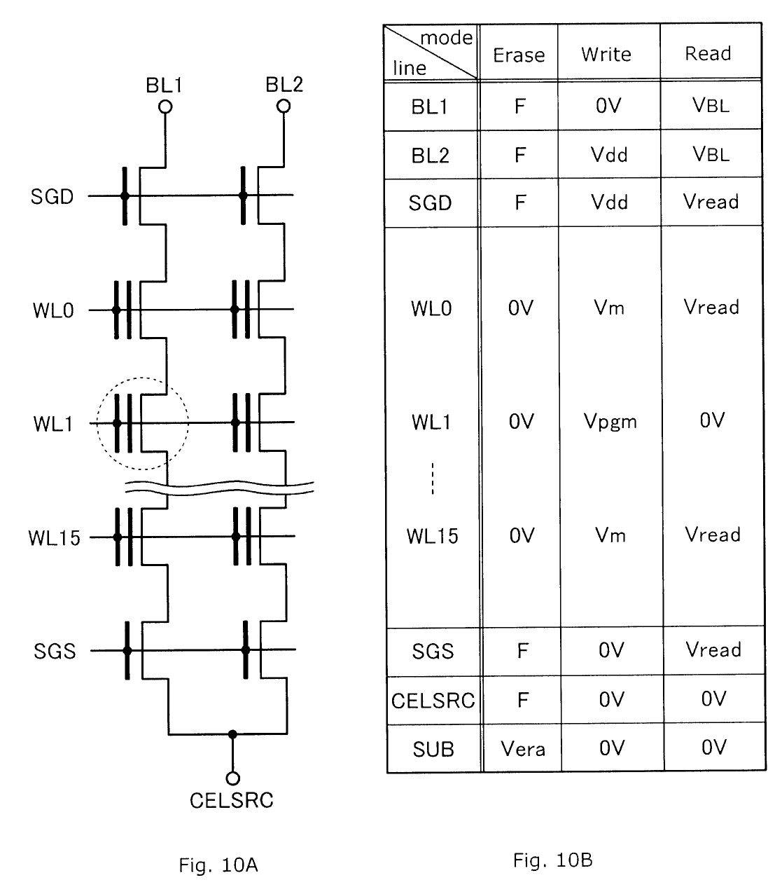

FIG. 10 shows the equivalent circuit of the NAND-type EEPROM according to the present embodiment.

To erase data in a selected block, the select gates SG, the bit lines BL and the common source line CELSRC in the selected block are set in a floating state, and all the word lines in the selected block are set to 0 V, while the silicon substrate 11 is provided with positive erasing voltage Vera. The erasing voltage Vera is a voltage increased, by a voltage increasing circuit (not shown), to a higher value than a power supply voltage Vdd, such as 15 V to 24 V.

Under such biasing conditions, the p-n junction region between the p-type silicon substrate 11 and n-type diffusion layer 13a in the silicon layer 13 is forward-biased through the silicon germanium layer 12, and the n-type diffusion layer 13a is charged to reach the erasing voltage Vera. Thereby, a large electric field is applied between the floating gate 31 and a channel in each memory cell M in the selected block. Accordingly, FN tunnel current causes the electrons in each floating gate 31 to be released through the tunnel oxide film 22 to the silicon substrate 11 side. As a result, the threshold value of each memory cell M is made in a negative erasing state (data “1” state).

In writing, data is written in the memory cells M on a page-unit basis. Here, a group of memory cells M arrayed along a word line WL is assumed as 1 page or 2 pages. In this event, the silicon substrate 11 is provided with 0 V (or small negative voltage), while the selected word lines WL are provided with a writing voltage Vpgm increased to 15 V to 20 V and other non-selected word lines WL are provided with a positive medium voltage Vm lower than the writing voltage Vpgm. In addition, each select gate SGD on the bit line BL side is provided with a Vdd, while each select gate SGS on the source line side is provided with 0 V. The common source line CELSRC is provided with 0 V or an appropriate positive voltage.

The bit lines BL are provided with 0 V (“0” written) or a Vdd (“1” written) in a manner that depends on the written data, prior to the application of the above writing bias voltage. Thereby, the channel of each of the NAND cells where “0” is to be written is provided with 0 V. On the other hand, the channel of each of the NAND cells where “1” is to be written is set in a floating state, after the corresponding select gate transistor SG1 is turned off when its source (opposite side to the side in contact with a bit line BL) is charged to reach Vdd−Vth (Vth is a threshold value of the select gate transistor SG1).

Under these conditions, when the word lines WL are provided with the above writing voltage Vpgm and the medium voltage Vm, FN tunnel current causes electrons to be injected in the floating gate of each cell selected for “0” writing. Accordingly, data “0” having a positive threshold value is written in such a cell. In each cell selected for “1” writing, the potential of a channel in a floating state is increased by capacity coupling, thereby preventing electrons from being injected therein. Accordingly, a data “1” state is maintained in such a cell.

Similarly, data is read from the memory cells M on a page-unit basis. In this event, the common source line CELSRC is set to 0 V, and the bit lines BL are previously charged to reach a predetermined positive voltage VBL and maintained in a floating state. In addition, the selected word lines WL are provided with a reading voltage Vr (for example, 0 V), and the other non-selected word lines WL as well as the select gate lines SGD and SGS are provided with a read pass voltage Vread that allows the cells to be turned on irrespective of data written therein.

Thus, if data “0” is written in the selected cell, the cell is not turned on not to discharge the corresponding bit lines BL. On the contrary, if data “1” is written in the selected cell, the cell is turned on to discharge the corresponding bit lines BL. Accordingly, data can be read out by detecting the voltages of the bit lines BL with a sense amplifier after a given time period of a bit line discharge operation.

The EEPROM of the present embodiment uses the semiconductor substrate 10 in which the silicon substrate 11 and the silicon layer 13 are partially connected to each other through a silicon germanium layer 12. Accordingly, the EEPROM of the present embodiment has a smaller junction capacity than that of an EEPROM using a semiconductor substrate formed only of a silicon substrate, and is thereby capable of high speed operation. The performances of the gates 31 and 32 for controlling the carrier concentration in the silicon layer 13 are similar to those in the case where an SOI substrate is used. However, in the silicon substrate 11 of the present embodiment, the silicon substrate 11 and the silicon layer 13 are partially connected to each other through the silicon germanium layer 12 unlike an SOI substrate so that a substrate floating effect can be eliminated. In addition, according to the present embodiment, substrate bias can be directly applied to the silicon layer 13. Therefore, carrier is easily eliminated from each floating gate 31.

In other words, in a NAND-type flash memory using a usual SOI substrate, it is generally difficult to collectively apply an erasing voltage to the channel bodies of all NAND cell units. To accomplish this, a special innovation such as the embedding of a back gate in the bottom surface of the channel body is necessary.

In contrast, in the present embodiment uses the silicon substrate 10 in which the silicon substrate 11 and the silicon layer 13 are partially connected to each other through the silicon germanium layer 12 is used. Accordingly, an erasing voltage for collective erasing can be applied to the channel bodies of the NAND cell units through the silicon substrate 11. Thus, collective erasing can be reliably performed.

### Second Embodiment

### Structure of the Second Embodiment

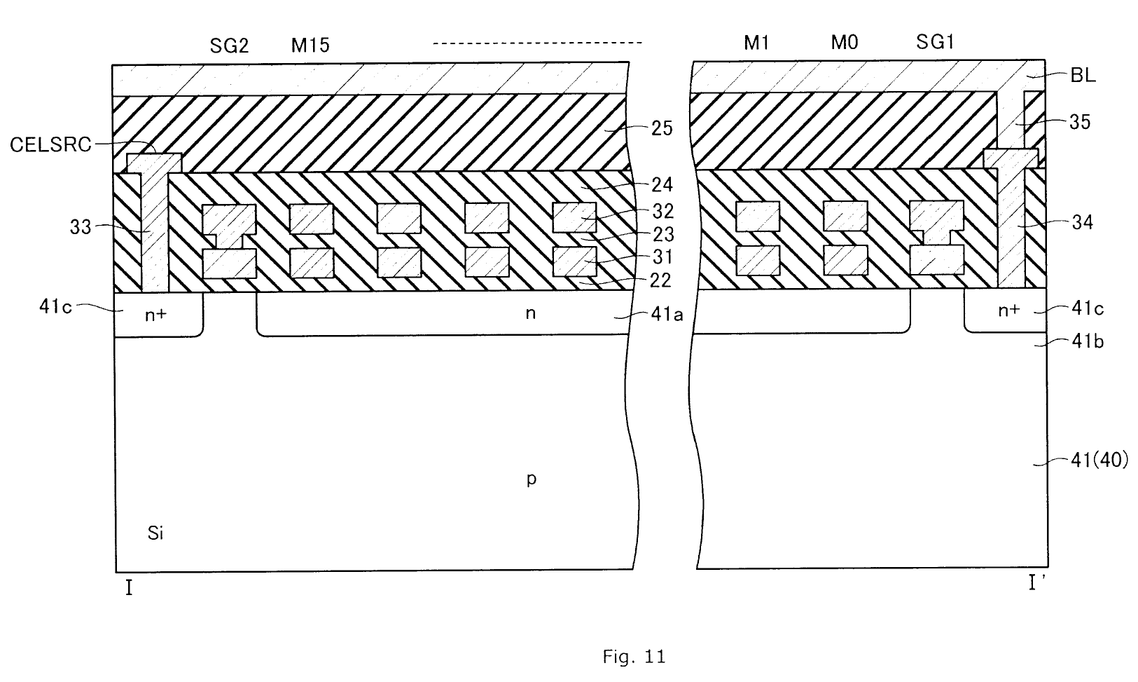

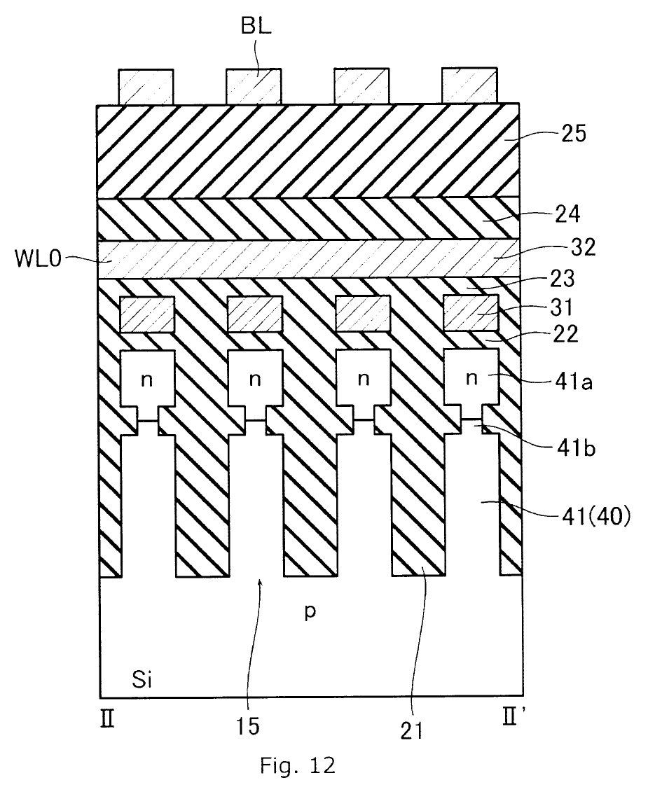

The second embodiment of the present invention will then be described based on FIGS. 11 to 12.

FIGS. 11 and 12 are cross-sectional views showing a NAND-type EEPROM according to the second embodiment of the present invention respectively corresponding to the FIGS. 2 and 3.

In the foregoing embodiment, the silicon germanium layer 12 is used to partially connect the silicon substrate 11 and silicon layer 13 at the center in the gate width direction. In the present embodiment, a semiconductor substrate 40 comprised of a single silicon substrate 41 not including a silicon germanium layer is used. An n-type diffusion layer 41a is formed by ion implantation in a region on the surface of the silicon substrate 41 in which the memory cells M are formed (channel bodies, and source and drain regions). The present embodiment is the same as the foregoing embodiment in the following points. The regions at the both ends of the memory cell formation region, where the channel bodies of the select gate transistors SG1 and SG2 are to be formed, remain p-type regions. In addition, n+-type contact regions 41c are formed adjacent to the outer sides of the select gate transistors SG1 and SG2.

In the present embodiment, the silicon substrate 41 includes element formation regions (active regions) in which a n-type diffusion layer 41a for the memory cell formation regions, areas right below the gates of the select gate transistors SG, and n+-type contact regions 41c are formed. In addition to them, narrow portions 41b are each formed by partially narrowing the element formation region in the gate width directions in the silicon substrate 41.

The other configuration is the same as that of the foregoing embodiment. Accordingly, the description of overlapping parts is eliminated.

### Manufacturing Method of the Second Embodiment

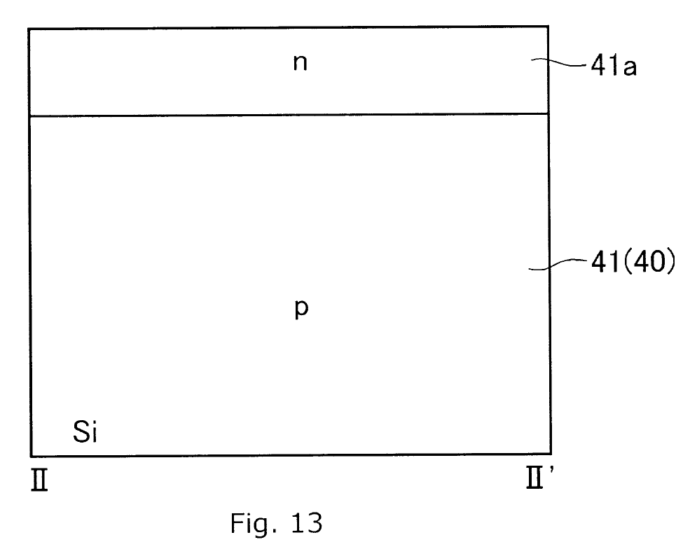

Hereinafter, a method for manufacturing the NAND-type EEPROM according to the present embodiment configured in the above manner will be described with reference to FIGS. 13 to 22.

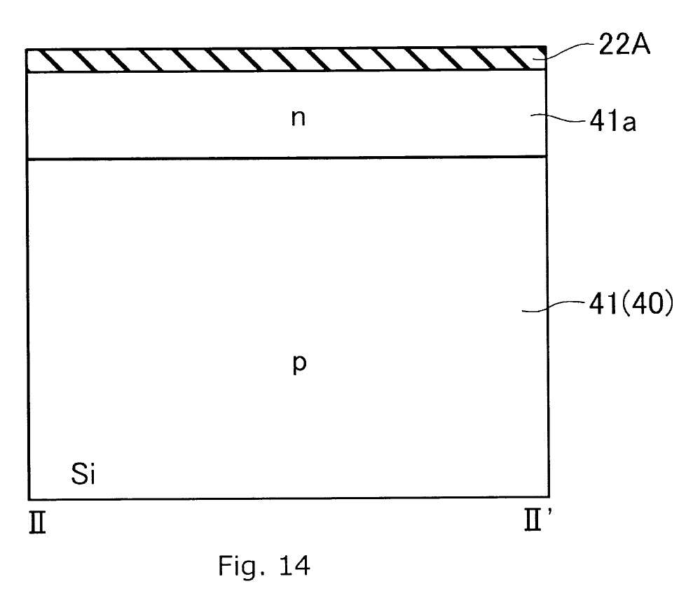

As shown in FIG. 13, n-type diffusion layer 41a is first formed by implanting ions of a n-type impurity into a region of the silicon substrate 41 in which the memory cells M are formed (channel bodies, and source and drain regions of the memory cells). As shown in FIG. 14, an oxide film 22A serving as a tunnel oxide film 22 is subsequently formed on the silicon substrate 41. The oxide film 22A may be formed by either heat-oxidizing the surface of the silicon substrate 41, or by stacking an oxide thereon.

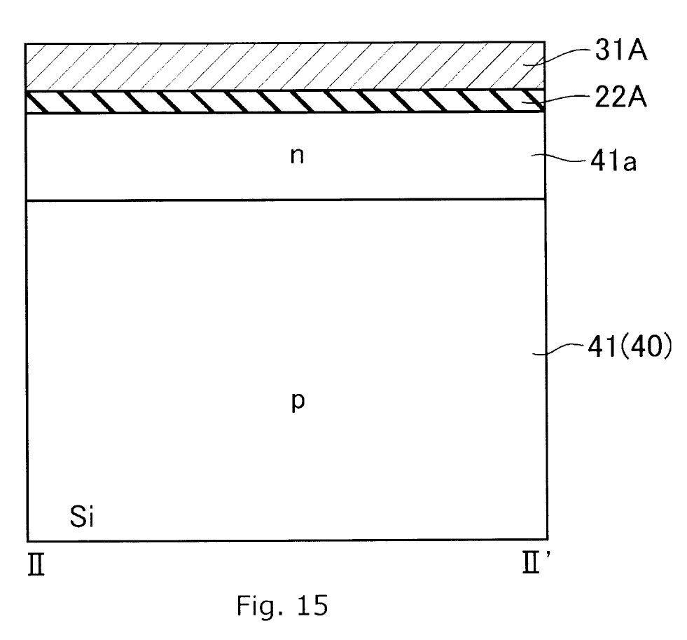

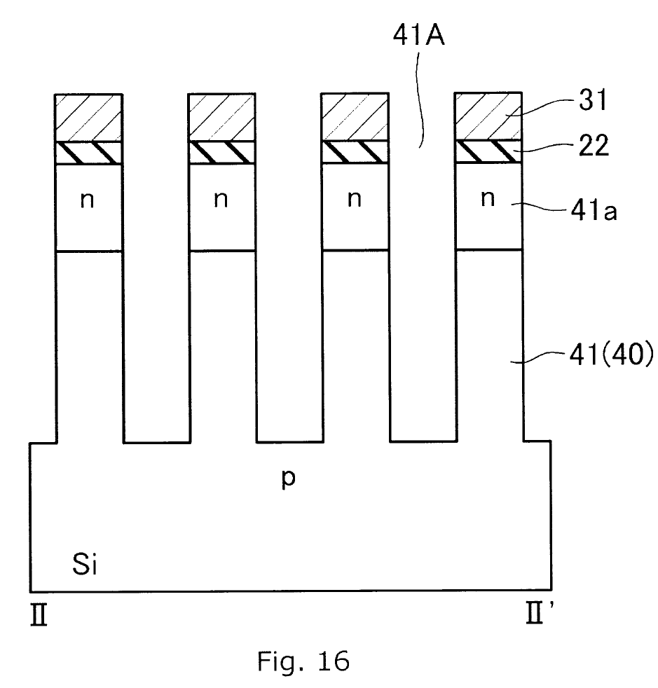

As shown in FIG. 15, a polysilicon layer 31A to serve as floating gates 31 is then formed on the oxide film 22A. Thereafter, trenches 41A for the STI are formed as shown in FIG. 16 by first patterning a resist film with a standard lithography technique, and by then etching the polysilicon layer 31A, the oxide film 22A, and the silicon substrate 41 to a desired depth through anisotropic etching using a reactive ion etching (RIE) method or the like. FIG. 16 shows the state in which the resist film is peeled off after etching.

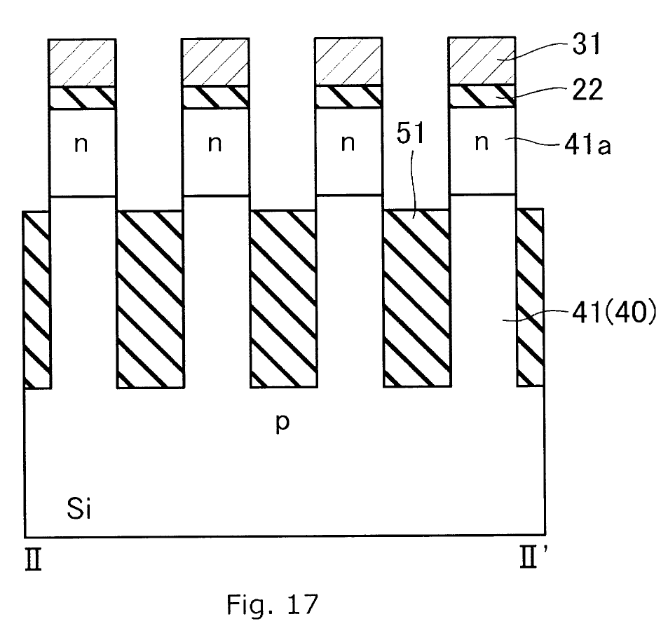

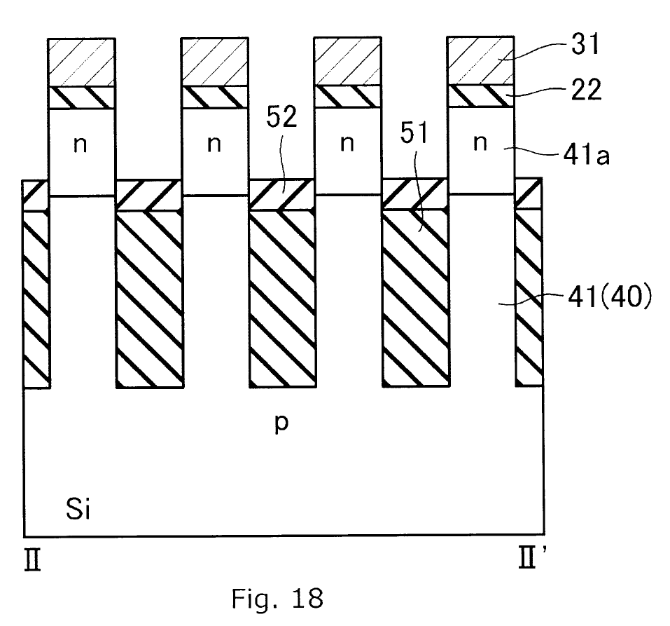

The formed trenches 41 are then partially filled with an oxide film 51 as shown in FIG. 17. The top surface of the oxide film 51 is set as high as the bottom edges of the narrow portions 41b of the silicon substrate 41. A silicon nitride film 52 is further formed on the oxide film 51 as shown in FIG. 18. The thickness of the silicon nitride film is set equal to the height of each narrow portion 41b of the silicon substrate 41. The processes of filling the trenches 41 with the oxide film 51 and the silicon nitride film 52 can be carried out using a recess process. Specifically, in each process, the trenches 41 are once entirely filled, and then the surface of the filling is planarized and recessed by etching.

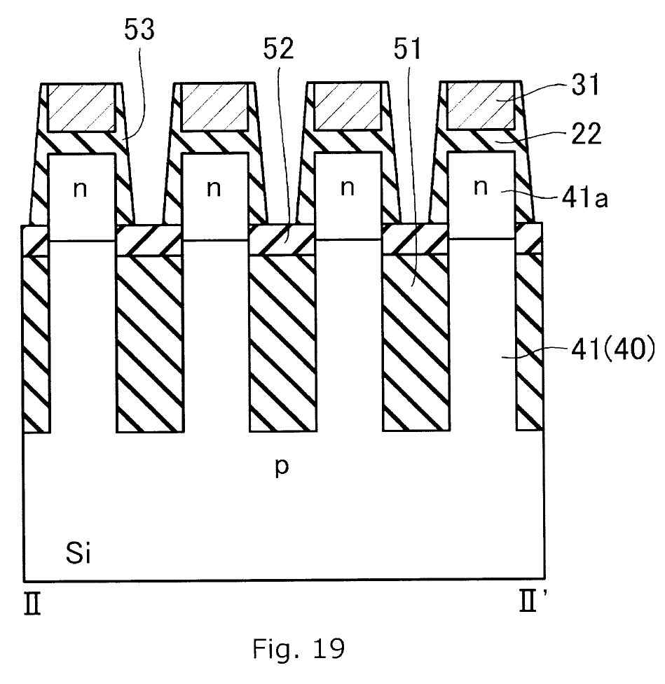

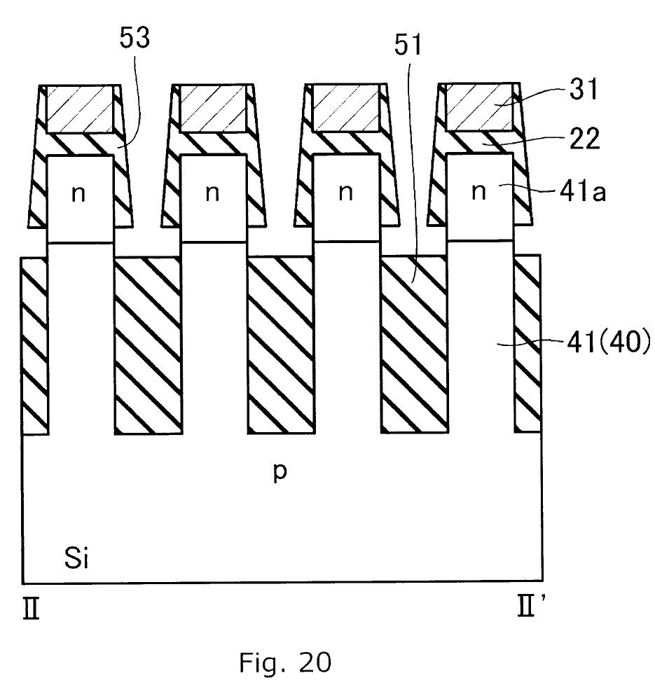

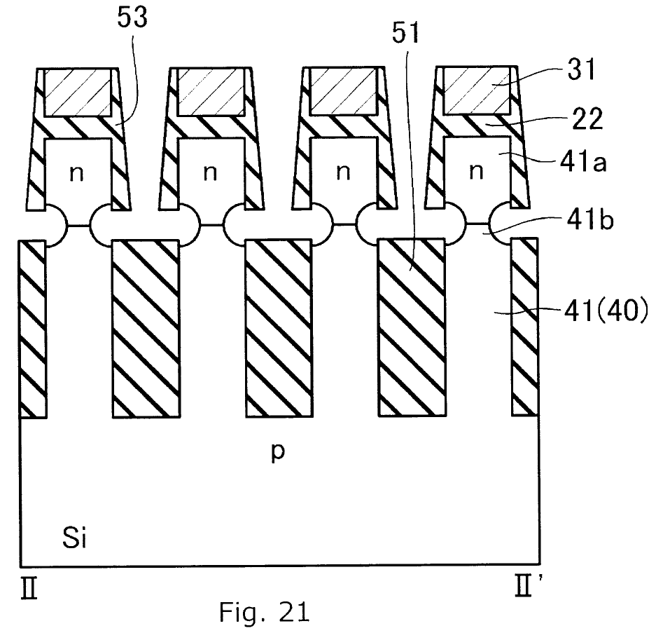

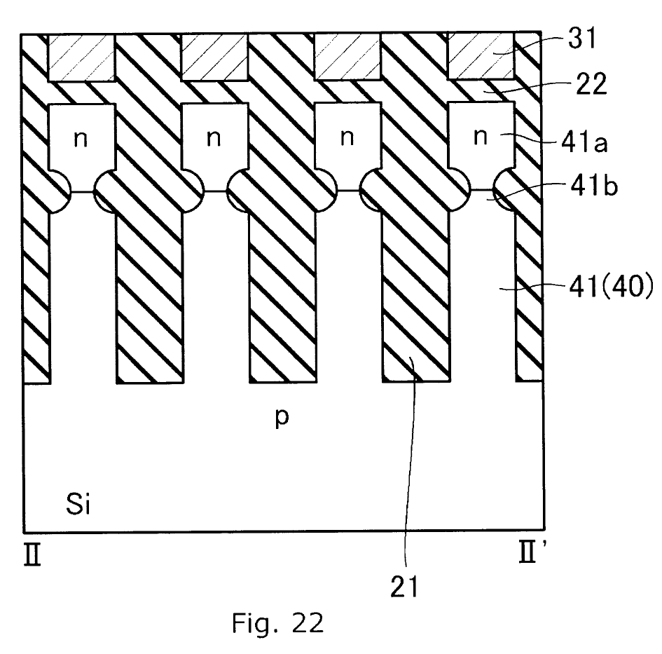

An oxide film 53 is then formed to cover the side walls of the trenches 41A as shown in FIG. 19. The silicon nitride film 52 is thereafter peeled off by a wet etching method as shown in FIG. 20. Subsequently, isotropic etching using a chemical dry etching (CDE) with CF4 gas or the like is carried out to partially engrave the portions, under the n-type diffusion layer 41a, of the silicon substrate 41 in horizontal directions as shown in FIG. 21. In this way, the narrow portions 41b are formed. Thereafter, the trenches 41A for the STI and the concave portions of the silicon substrate 41 engraved in horizontal directions are filled with an oxide film, and thereby an element isolation insulating film 21 can be formed as shown in FIG. 22.

The subsequent processes are the same as those of the forgoing embodiment.

The manufacturing method of the present embodiment includes somewhat more complicated processes than those of the foregoing embodiment, but has an advantage that a single silicon substrate can be used therein.

### Physical Properties of the Embodiment of the Present Invention

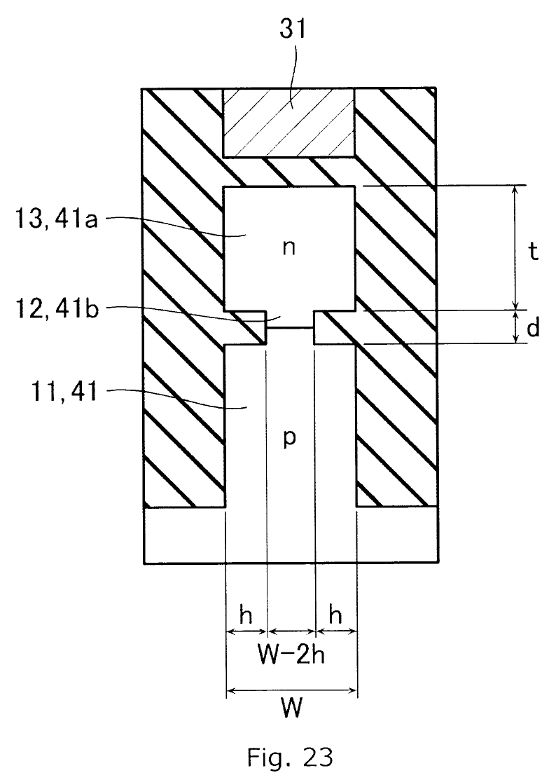

FIG. 23 diagrammatically shows the main part of the embodiment of the present invention.

The thickness t of the silicon layers 13 and 41a to serve as active regions on the surface can be set at any appropriate value depending on the type of the device such as a CMOS transistor and a memory cell and the application. When the device is configured to operate with the silicon layer depleted completely, the film thickness t is preferably approximately 10 nm to 20 nm. The height d of each narrow portion 41b can also be set at any value. In the case where the silicon germanium layer 12 is used as shown in the first embodiment, the height d can be set by adjusting the film thickness of the silicon germanium layer 12. In the second embodiment, the height d can be set by adjusting the film thickness of the silicon nitride layer 52. In the present embodiment, d=10 nm. The engraving depth h of each narrow portion 12a or 41b is necessary to meet W<2h. Here, W indicates the width of the silicon layer 13 or 41a in the gate width direction. When h is too large, the strength of each narrow portion 12a or 41b is reduced. When h is too small, the silicon layer cannot be completely depleted and the junction capacity cannot sufficiently be reduced. Accordingly, the width (W−2h) of each narrow portion 12a or 41b is preferably set within a range 0.2W≦W-2h≦0.8W. In the present embodiment, W=30 nm and h=10 nm.

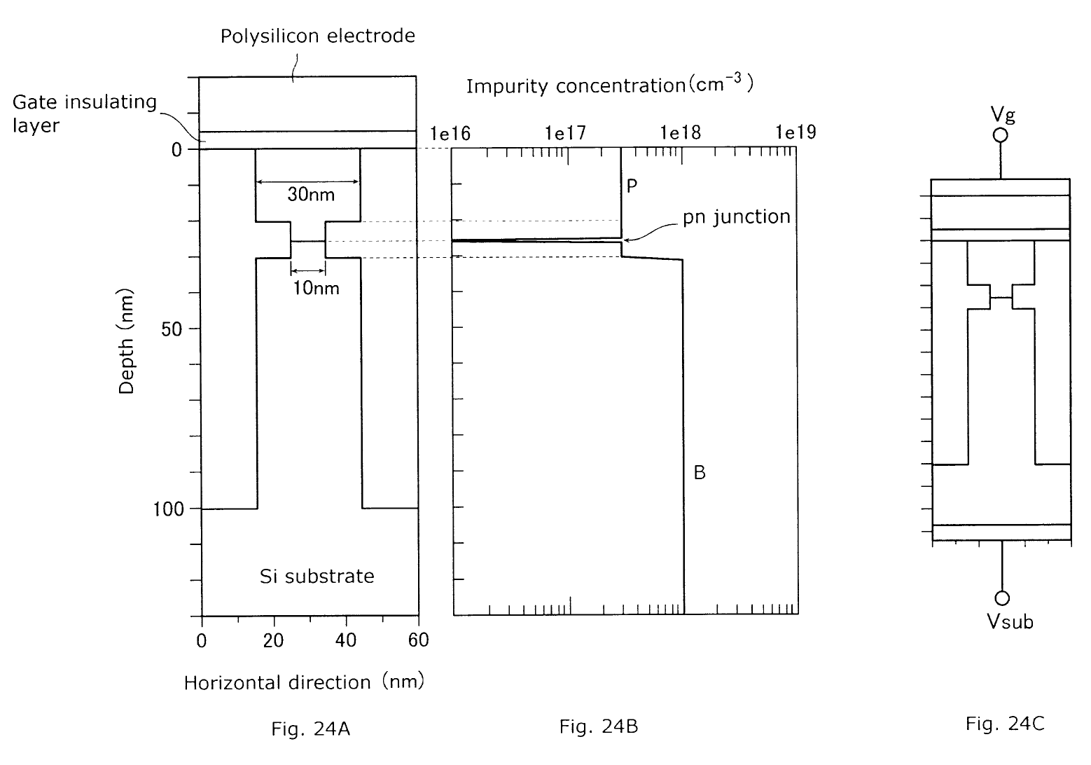

FIG. 24 diagrammatically shows the impurity concentration distribution of the second embodiment. Note that although descriptions are given of an example in which the narrow portions are formed of a silicon layer (the second embodiment) herein, the same holds for an example in which the narrow portions are formed of a silicon germanium (the first embodiment).

Any type and concentration of the impurities in each region of the silicon substrate can be employed according to whether the region is a channel region of the element, a diffusion region such as a source or drain region. Here, the channel region of the EEPROM is taken as an example for description. In this case, the impurity concentration is preferably 1e16 cm−3 to 1e19 cm−3 for causing the active regions to be completely depleted and to be conductive according to the gate voltage. In the present embodiment, description will be given of an example in which the silicon substrate is doped with phosphorus at 3e17 cm−3.

Any kind of impurities can be used in the narrow portions in the semiconductor. However, under conditions that the upper silicon layer is completely depleted during operation, it is preferable to use impurities of a conductivity type opposite to that of the impurities in the silicon layer, or impurities of the same conductivity type as that of the silicon layer under the narrow portion. Alternatively, impurities may be disposed so as to form a junction in each narrow portion. In the present embodiment, each narrow portion has a p-n junction in the center thereof. Specifically, the upper narrow portion above the junction near the silicon layer is doped with phosphorus, which is the same impurities as those in the silicon layer, at the same concentration of 3e17 cm−3. On the other hand, the lower narrow portion under the junction near the silicon substrate is doped with boron at a concentration of 3e17 cm−3 in the present embodiment. A portion under each narrow portion near the silicon substrate is doped with boron at a concentration of 1e18 cm−3 in the present embodiment. To enhance a substrate bias effect, doping may be performed at a higher concentration. In addition, an uneven concentration distribution having a peak in the center of each active region may be employed.

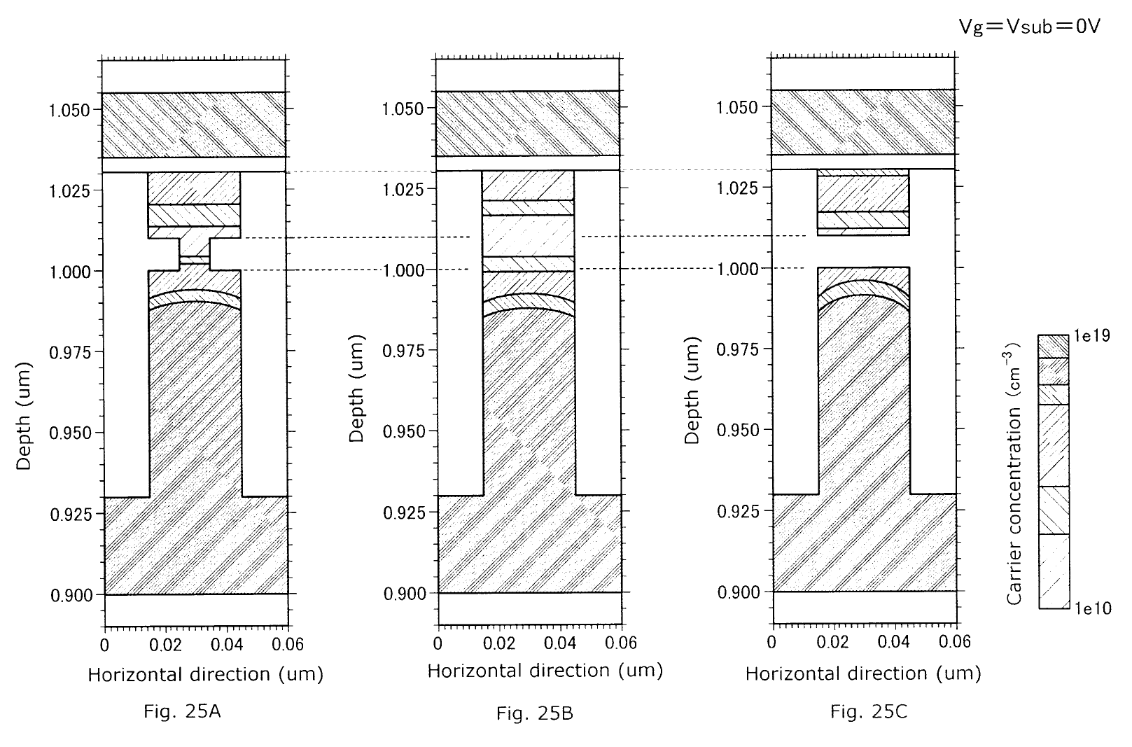

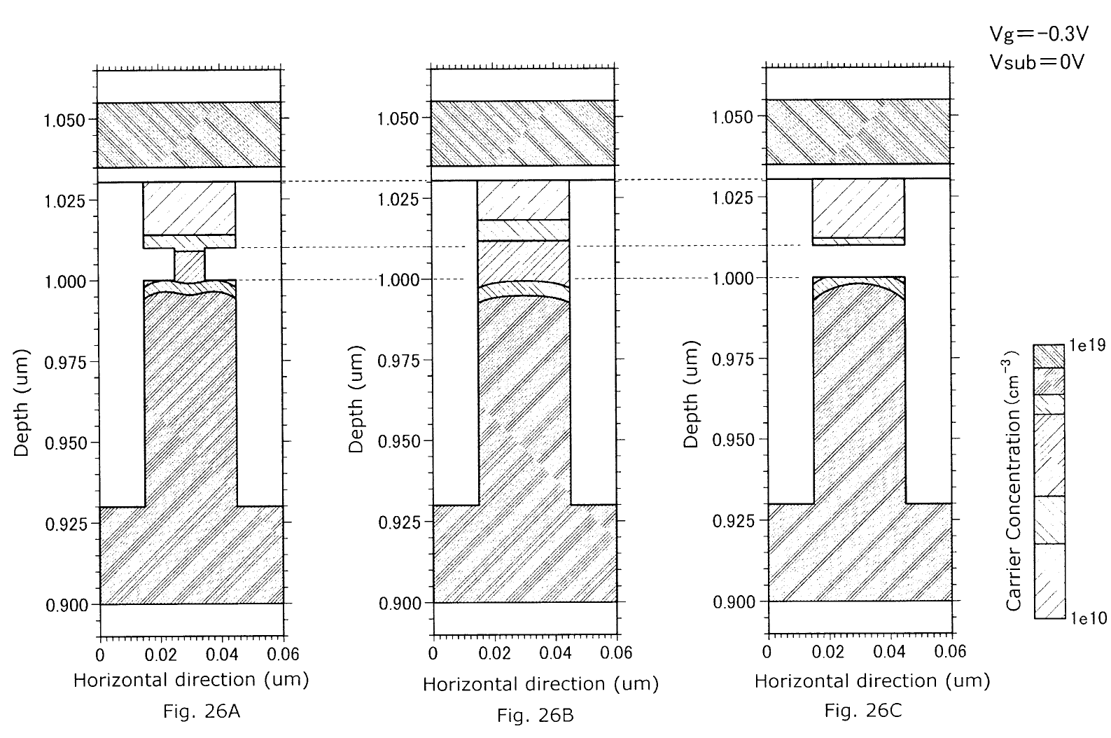

FIGS. 25 and 26 show carrier concentration distributions in the silicon substrates and the polysilicon layers obtained by simulation in order to show the electric properties of the present embodiment in comparison with those of conventional examples. Here, the absolute value of the difference in concentration between electrons and holes is defined as a carrier concentration. FIGS. 25A and 26A show carrier concentration distributions of an embodiment of the present invention. FIGS. 25B and 26B show those of the conventional example 1 having no narrow portion. FIGS. 25C and 26C show those of the conventional example 2 using the SOI substrate. The carrier concentration distributions are obtained under the following assumptions. A gate electrode is schematically disposed on and connected to the polysilicon layer at the top. A substrate electrode is connected to the bottom edge of the silicon substrate.

FIG. 25 shows the case where a gate voltage Vg=0 V, and a substrate voltage Vsub=0 V. As is clear from the figure, at a gate voltage Vg of 0 V, a sufficient amount of carrier is present in the active regions in the structure of the present embodiment as in the conventional example 2 using the SOI.

FIG. 26 shows the case where a gate voltage Vg=−0.3 V, and a substrate voltage Vsub=0 V. As is clear from the figure, the carrier concentration in the silicon layer on the surface is reduced along with the negative increase of the gate voltage Vg (approximately 1e10 cm−3) so that the silicon layer can be sufficiently depleted as in the conventional example 2 using the SOI. On the contrary, it is shown that the layer is sufficiently depleted in the conventional example 1.

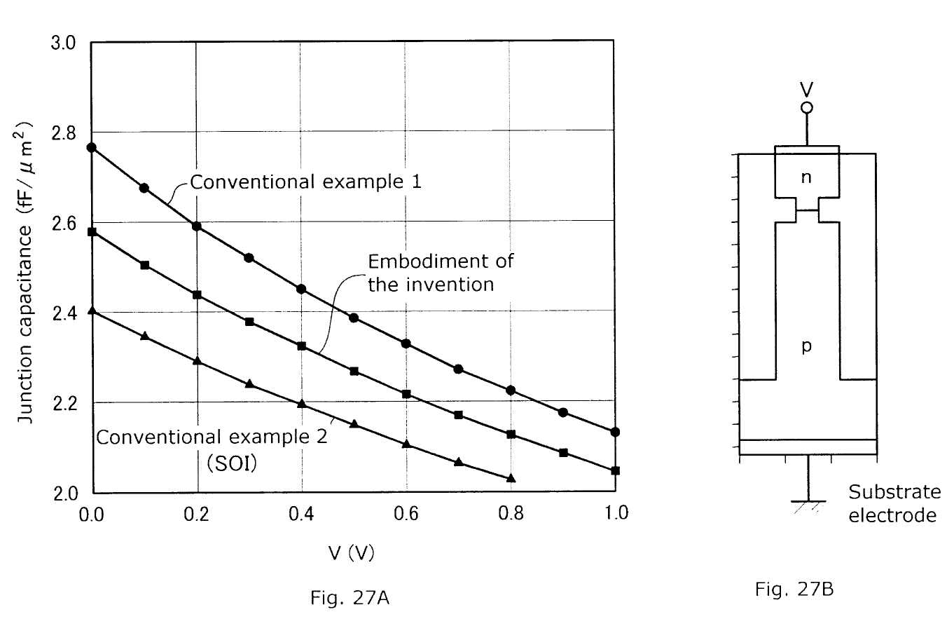

FIG. 27 shows relationships between the voltage applied to the silicon substrate and the p-n junction capacities. As is clear from the figure, the junction capacity is reduced in the present embodiment as compared to in the structure of the conventional example 1 having no narrow portion. As a result, a semiconductor element having a lower parasitic capacity than that of the conventional structure can be accomplished.

According to the embodiments of the present invention, the performance of the gate electrode for controlling the carrier concentration in the surface silicon layer is similar to that in the case where the SOI substrate is used. However, in each embodiment of the present invention, the surface silicon layer is directly connected to the silicon substrate unlike the case where the SOI substrate is used so that a substrate floating effect can be eliminated. In addition, in the present embodiment, the substrate bias can be directly applied to the surface silicon layer. Accordingly, applying the present invention to, for example, a NAND-type EEPROM provides an effect that carrier can be easily eliminated from each floating gate.

The present invention is not limited to the above described embodiments. For example, the modifications listed below are possible.

(a) In the above embodiment, the present invention is applied to the memory cells and select gate transistors of the NAND-type EEPROM. However, the present invention can be generally applied to usual field-effect transistors such as a metal-oxide-semiconductor field-effect transistor (MOSFET) as well as memories of polysilicon-oxide-nitride-oxide-semiconductor (SONOS) and metal-oxide-nitride-oxide-semiconductor (MONOS) structures.

(b) The present invention can be similarly applied to cases where p-type and n-type are replaced with each other in the above embodiments.

(c) Each narrow portion may be formed not in the center but at an edge of the upper silicon layer.

(d) A method in which the silicon layer is formed as an intrinsic semiconductor film containing few impurities, and transformed into p-type (or n-type) by ion implantation after the crystallization thereof may be used.

Embodiments of the invention have been described with reference to the examples. However, the invention is not limited thereto.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a transistor including a semiconductor substrate, an insulating film formed on the semiconductor substrate, and a gate stacked above the semiconductor substrate with the insulating film placed in between; and
element isolation trenches formed in the semiconductor substrate to define an element formation region in which the transistor is to be formed, wherein
the semiconductor substrate includes a narrow portion therein, the narrow portion formed by partially narrowing down the element formation region from the side surfaces of the element isolation trenches in the gate width directions in the substrate.

2. The semiconductor device according to claim 1, wherein
when the width of the element formation region at the substrate surface in the gate width direction is W, the width of the narrow portion in the gate width direction is within a range of 0.2 W to 0.8 W, inclusive.

3. The semiconductor device according to claim 1, wherein
in the semiconductor substrate, the narrow portion is formed of SiGe, and portions above and below the narrow portion are formed of Si.

4. The semiconductor device according to claim 2, wherein
in the semiconductor substrate, the narrow portion is formed of SiGe, and portions above and below the narrow portion are formed of Si.

5. A nonvolatile semiconductor memory device, comprising:
a plurality of memory cells each including: a semiconductor substrate; a first insulating film formed on the semiconductor substrate, a floating gate formed above the semiconductor substrate with the first insulating film placed in between, a second insulating film formed on the floating gates, and a control gate formed above the floating gate with the second insulating film placed in between; and
element isolation trenches extending in the gate length directions to isolate from each other the memory cells adjacent in the gate width directions, wherein
the semiconductor substrate includes a narrow portion therein, the narrow portion formed by partially narrowing down an element formation region of the substrate from the side surfaces of the element isolation trenches in the gate width directions, the element formation region defined by the element isolation trenches.

6. The nonvolatile semiconductor memory device according to claim 5, wherein
when the width of the element formation region at the substrate surface in the gate width direction is W, the width of the narrow portion in the gate width direction is within a range of 0.2 W to 0.8 W, inclusive.

7. The nonvolatile semiconductor memory device according to claim 5, wherein
in the semiconductor substrate, the narrow portion is formed of SiGe, and portions above and below the narrow portion are formed of Si.

8. The nonvolatile semiconductor memory device according to claim 6, wherein
in the semiconductor substrate, the narrow portion is formed of SiGe, and portions above and below the narrow portion are formed of Si.

9. The nonvolatile semiconductor memory device according to claim 5, wherein a pn junction is provided in the narrow portion.

10. The nonvolatile semiconductor memory device according to claim 6, wherein a pn junction is provided in the narrow portion.

11. A method of manufacturing a semiconductor device, comprising:
forming an insulating film on a semiconductor substrate;
forming an electrode layer to serve as a gate electrode on the insulating film;
forming element isolation trenches extending from the electrode layer to the inside of the semiconductor substrate to define an element formation region in the semiconductor substrate;
selectively etching the side surfaces of the element isolation trenches of the semiconductor substrate to engrave a portion of the semiconductor substrate in directions approximately perpendicular to the side surfaces, the portion of the semiconductor substrate being in the element formation region below the top surface of the substrate; and
filling the element isolation trench with an element isolation insulating film after selectively etching the side surfaces.
